(19) United States
(12) Patent Application Publication
(10) Pub. No.: US 2026/0143796 A1
(43) Pub. Date: May 21, 2026

(54) SEMICONDUCTOR DEVICE AND SEMICONDUCTOR CHIP COMPRISING THE SAME

(71) Applicant: Samsung Electronics Co., Ltd., Suwon-si (KR)

(72) Inventors: Inhyun Song, Suwon-si (KR); Kyoungwoo Lee, Suwon-si (KR); Myungjin Chung, Suwon-si (KR); Eunguk Chung, Suwon-si (KR); Keunhwi Cho, Suwon-si (KR); Wookhyun Jo, Suwon-si (KR); Hanbyul Choi, Suwon-si (KR)

(21) Appl. No.: 19/207,475

(22) Filed: May 14, 2025

(30) Foreign Application Priority Data
Nov. 20, 2024 (KR) 10-2024-0165993

(51) Int. Cl. H10D 84/83; H01L 23/528; H10D 30/00; H10D 30/01; H10D 62/10; H10D 62/13; H10D 64/23; H10D 84/01

(52) U.S. Cl. CPC H10D 84/832; H10D 30/502; H10D 62/121; H10D 62/151; H10D 64/256; H10W 20/427; H10W 20/43; H10D 30/0191; H10D 84/0149

(57) ABSTRACT

A semiconductor device includes an active region extending in a first direction; a gate structure on the active region and extending in a second direction intersecting the first direction; source/drain regions on side surfaces of the gate structure and on the active region; front side contacts on a first side of the source/drain regions; backside contacts at least partially penetrating the active region and on a second side of the source/drain regions opposite the first side; and an interlayer insulating layer on the gate structure, on the source/drain regions, and on the front side contacts. An entire upper surface of the gate structure that is opposite the active region in a third direction perpendicular to the first and second directions is in contact with the interlayer insulating layer.

### CROSS-REFERENCE TO RELATED APPLICATION(S)

This application claims benefit of priority to Korean Patent Application No. 10-2024-0165993 filed on Nov. 20, 2024 in the Korean Intellectual Property Office, the disclosure of which is incorporated herein by reference in its entirety.

### TECHNICAL FIELD

The present disclosure relates to a semiconductor device and a semiconductor chip including the same.

### BACKGROUND

With increased in demand for high performance, high speed, and/or multifunctionality of semiconductor devices, integration of semiconductor devices has increased. In accordance with the trend toward high integration of semiconductor devices, semiconductor devices having a BackSide Power Delivery Network (BSPDN) structure, in which a power rail is disposed on a backside of a wafer, have been developed. Additionally, research has been conducted on structures and methods for Failure Analysis (FA) of semiconductor devices having the BSPDN structure.

### SUMMARY

An aspect of the present disclosure provides a semiconductor device capable of heat transfer or electrical signal transfer between upper and lower portions using a dummy and a semiconductor chip including the same.

A semiconductor device according to example embodiments may include: an active region extending in a first direction; a gate structure on the active region and extending in a second direction intersecting the first direction; source/drain regions on side surfaces of the gate structure and on the active region; front side contacts on a first side of the source/drain regions; backside contacts at least partially penetrating the active region and on a second side of the source/drain regions opposite the first side; and an interlayer insulating layer on the gate structure, on the source/drain regions, and on the front side contacts. An entire upper surface of the gate structure that is opposite the active region in a third direction perpendicular to the first and second directions may be in contact with the interlayer insulating layer.

A semiconductor device according to example embodiments may include: an active layer including a core region, and a dummy region adjacent the core region, the core region including a plurality of gate structures spaced apart from each other in a first direction and extending in a second direction intersecting the first direction, and a plurality of source/drain regions on side surfaces of the plurality of gate structures; a front interconnection layer on a first side of the active layer and including a front interconnection structure and a front insulating layer on the front interconnection structure; and a rear interconnection layer on a second side of the active layer opposite the first side, and including a rear interconnection structure and a rear insulating layer on the rear interconnection structure The plurality of gate structures may include first gate structures in the dummy region and second gate structures in the core region, the plurality of source/drain regions may include first source/drain regions on side surfaces of the first gate structures, and second source/drain regions on side surfaces of the second gate structures, the active layer may further includes first front side contacts extending into the first source/drain regions from an upper surface thereof and first backside contacts extending into the first source/drain regions from a lower surface thereof, the front interconnection structure may overlaps the second gate structures in a third direction perpendicular to the first direction and the second direction, and may be electrically connected to the second gate structures, the rear interconnection structure may overlaps the second source/drain regions in the third direction and may be electrically connected to the second source/drain regions, and the first gate structures may not overlap the front interconnection structure and the rear interconnection structure in the third direction.

A semiconductor device according to example embodiments may include: an active layer including a first region and a second region; a first active region extending in the first region in a first direction; a second active region extending in the second region in the first direction; a first gate structure extending in a second direction intersecting the first direction and on the first active region of the first region; a second gate structure extending on the second active region of the second region and in the second direction; first source/drain regions on side surfaces of the first gate structure and on the first active region; second source/drain regions on side surfaces of the second gate structure and on the second active region; first front side contacts on a first side of the first source/drain regions; a second front side contact on a first side of at least one of the second source/drain regions; first backside contacts on a second side of the first source/drain regions opposite the first side; a second backside contact on a second side of at least one of the second source/drain regions opposite the first side; a lower blocking structure at least partially penetrating the second active region, on the second gate structure, and separating the second active region; an upper via on the second front side contact; a gate contact on the second gate structure opposite the lower blocking structure; and a front interconnection structure including a first front transmission line extending in the first direction on the active layer and a second front transmission line extending in the second direction, wherein the front interconnection structure may be electrically connected to the second gate structure through the gate contact, and the first gate structure may be electrically isolated from the front interconnection structure.

In a semiconductor device having a BSPDN structure, a front side contact and a backside contact are connected to a dummy source/drain region, so that electrical signal transmission and heat exchange between an upper portion and a lower portion may occur even in a dummy region, thereby providing a semiconductor device having improved reliability and heat dissipation characteristics and a semiconductor chip including the same.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view illustrating a semiconductor chip according to example embodiments;

FIG. 2A is a schematic plan view illustrating a semiconductor device according to example embodiments;

FIG. 2B is a schematic cross-sectional view illustrating a semiconductor device according to example embodiments;

FIG. 2C is a schematic partial enlarged view illustrating a semiconductor device according to example embodiments;

FIG. 2D is a schematic partial enlarged view illustrating a semiconductor device according to example embodiments;

FIG. 3A is schematic plan views illustrating a semiconductor device according to example embodiments;

FIG. 3B is a schematic cross-sectional view illustrating a semiconductor device according to example embodiments;

FIG. 3C is a schematic cross-sectional view illustrating a semiconductor device according to example embodiments;

FIG. 3D is schematic cross-sectional views illustrating a semiconductor device according to example embodiments;

FIGS. 4 and 5 are cross-sectional views illustrating a semiconductor device according to example embodiments;

FIGS. 6A and 6B are cross-sectional views illustrating a semiconductor device according to example embodiments;

FIGS. 7 and 8 are plan views illustrating a semiconductor device according to example embodiments;

FIGS. 9, 10, 11, 12, 13, 14, 15A, 16A and 17A are cross-sectional views illustrating a method of manufacturing a semiconductor device according to example embodiments of the present disclosure according to a process sequence; and

FIGS. 15B, 16B and 17B are cross-sectional views illustrating a method of manufacturing a semiconductor device according to example embodiments of the present disclosure.

### DETAILED DESCRIPTION OF EMBODIMENTS

Hereinafter, example embodiments of the present disclosure will be described with reference to the accompanying drawings. Hereinafter, it may be understood that spatially relative expressions such as “on,” “above,” “upper,” “below,” “beneath,” “lower,” and “side,” merely refer to the drawings unless otherwise stated. It will be understood that such spatially relative terms are intended to encompass different orientations of the device in use or operation in addition to the orientation depicted in the figures.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout.

As used herein, a “level” of an element or component may refer to a distance of the element or component (or a sublayer of a layer structure including the element or component therein) from a reference layer or surface.

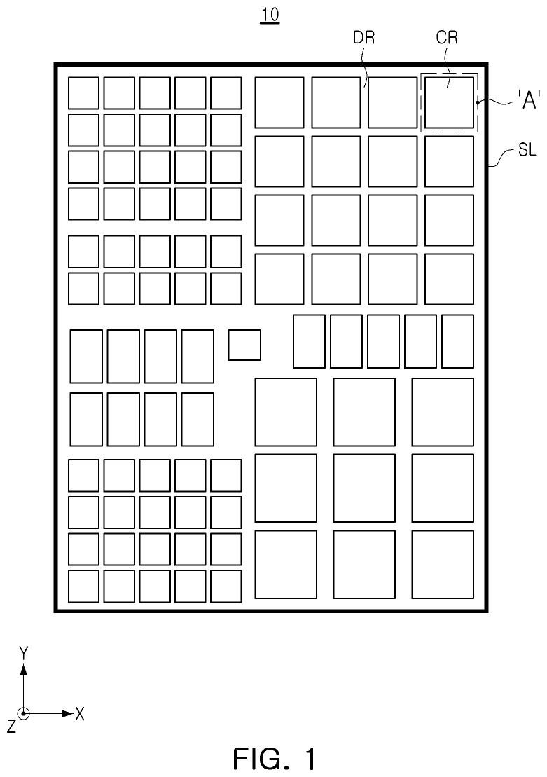

FIG. 1 is a schematic plan view illustrating a semiconductor chip according to example embodiments. For convenience of description, only some components of the semiconductor chip are illustrated in FIG. 1.

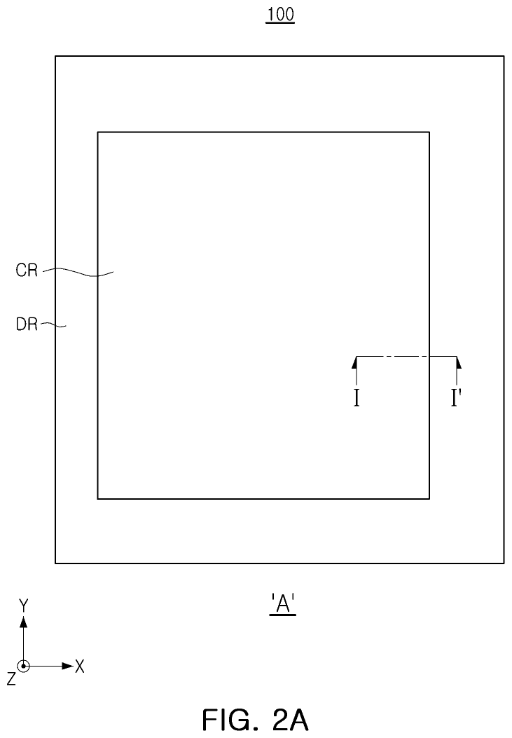

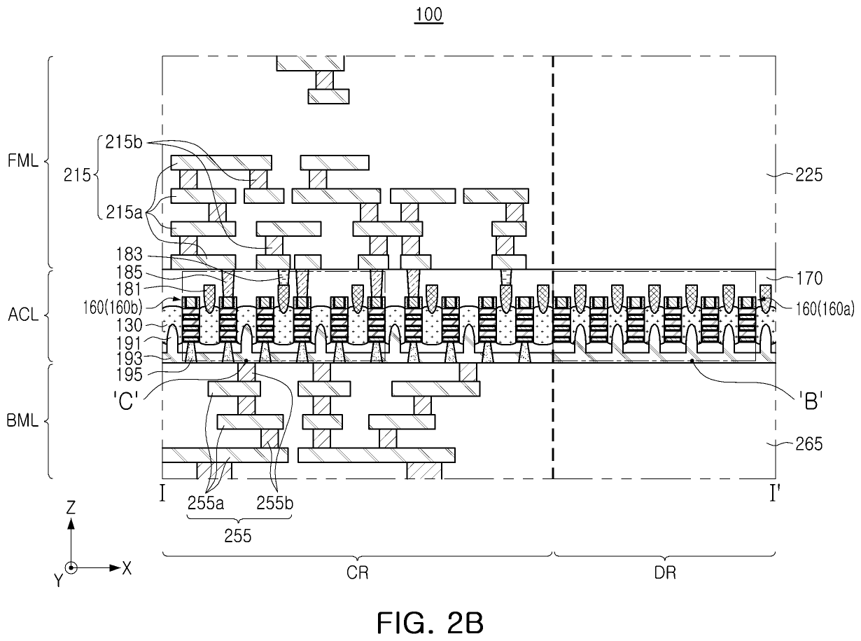

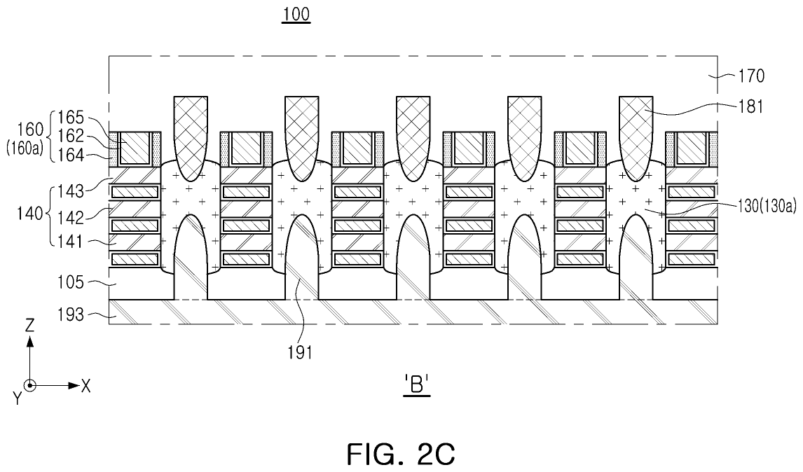

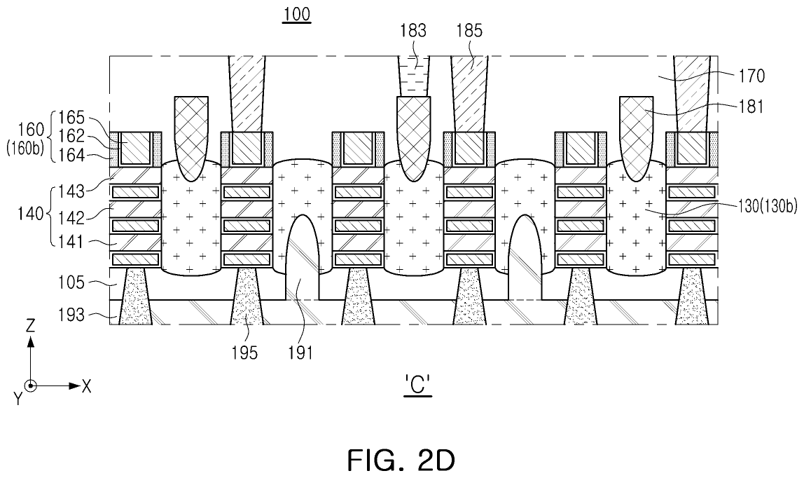

FIG. 2A is a schematic plan view illustrating a semiconductor device according to example embodiments. FIG. 2A illustrates an enlarged view of region ‘A’ of FIG. 1 and illustrates a semiconductor device disposed in a corresponding region. For convenience of description, in FIG. 2A, components of the semiconductor device are omitted.

FIG. 2B is a schematic cross-sectional view illustrating a semiconductor device according to example embodiments. FIG. 2B schematically illustrates a cross-section taken along the line I-I′ of the semiconductor device of FIG. 2A.

FIG. 2C is a schematic partial enlarged view illustrating a semiconductor device according to example embodiments. FIG. 2C is an enlarged view of region ‘B’ of FIG. 2B.

FIG. 2D is a schematic partial enlarged view illustrating a semiconductor device according to example embodiments. FIG. 2D is an enlarged view of region ‘C’ of FIG. 2B.

Referring to FIG. 1, a semiconductor chip 10 may include a plurality of core regions CR, a dummy region DR surrounding the plurality of core regions, and a residual scribe lane SL surrounding the dummy region DR.

The plurality of core regions CR may be arranged in a grid shape with the same or different sizes, and may be regions in which transistors are disposed.

The dummy region DR may surround the plurality of core regions CR and may be disposed between the plurality of core regions CR. The plurality of core regions CR may be separated from each other by the dummy region DR. Within the dummy region DR, components identical to or similar to those disposed in the plurality of core regions CR may be disposed, but such components may be dummy components that do not transmit electrical signals or power.

The residual scribe lane SL may surround the dummy region DR, and may form an edge of the semiconductor chip 10. The residual scribe lane SL may be a scribe lane remaining after cutting semiconductor chips into individual chip units along the scribe lane in a wafer unit including semiconductor chips disposed in a grid pattern and scribe lanes extending between the semiconductor chips. Unlike the semiconductor devices that may be disposed in the core region CR and the dummy region DR, the semiconductor devices may not be disposed in the residual scribe lane SL.

Referring to FIGS. 2A, 2B, 2C, and 2D, a semiconductor device 100 may include a core region CR and a dummy region DR surrounding the core region CR, and may include an active layer ACL, a front interconnection layer FML disposed on the active layer ACL, and a rear interconnection layer BML disposed below the active layer ACL.

In a semiconductor device including a non-functional region within the dummy region DR or the core region CR, during a rear process, not only in the core region CR, but also in a source/drain region 130 of the dummy region DR or a source/drain region 130 of the non-functional region within the core region CR, a structure in which front and rear surfaces are connected may be formed by connecting front side contacts 181 and backside contacts 191. The corresponding components are non-functional components that do not operate as transistors, but the corresponding components of the present disclosure may transmit an electrical signal between an upper portion and a portion for the execution of a Failure Analysis (FA) as necessary, and heat generated and transmitted in the core region CR may be transmitted between the upper portion and the lower portion, thereby providing a semiconductor device having improved reliability and heat dissipation capability.

The active layer ACL may include components formed by a Front End Of Line (FEOL) process, for example, a transistor including a gate structure. The front interconnection layer FML may be disposed on the active layer ACL and may include components formed by a rear End Of Line (BEOL) process, and such components may transmit electrical signals to components formed in the active layer ACL. The rear interconnection layer BML may be disposed below the active layer ACL and may include components transmitting power to components formed in the active layer ACL. Each of the active layer ACL, the front interconnection layer FML and the rear interconnection layer BML may include a core region CR and a dummy region DR surrounding the core region. In terms of individual core regions CR, the dummy region DR may be a ring shape surrounding the core region CR. Depending on the description method, the core region CR and the dummy region DR may be defined by the active layer ACL. For example, the core region CR may be a region in which transistors of a semiconductor device are disposed, and the dummy region CR may be a region in which dummy transistors are disposed.

The active layer ACL may include an active region 105, channel structures 140 including first to third channel layers 141, 142 and 143 vertically apart from each other on the active region 105, gate structures 160 extending by intersecting the active region 105 and respectively including a gate electrode 165, source/drain regions 130 connected to the channel structures 140, front side contacts 181 and backside contacts 191 connected to the source/drain regions 130, a lower blocking structure 195 penetrating through the active region 105 below the gate structures 160, and a rear power rail 193 connected to the backside contacts 191 below the active region 105. The active layer ACL of the semiconductor device 100 may further include an interlayer insulating layer 170.

In the semiconductor device 100, the active region 105 may have a fin structure, and the gate electrode 165 may be disposed between the active region 105 and the channel structure 140, may be disposed between the first to third channel layers 141, 142 and 143 of the channel structure 140, and may be disposed on the channel structure 140. Accordingly, the semiconductor device 100 may include transistors having a MBCFET™ (Multi Bridge Channel FET) structure, which is a gate-all-around type field effect transistor.

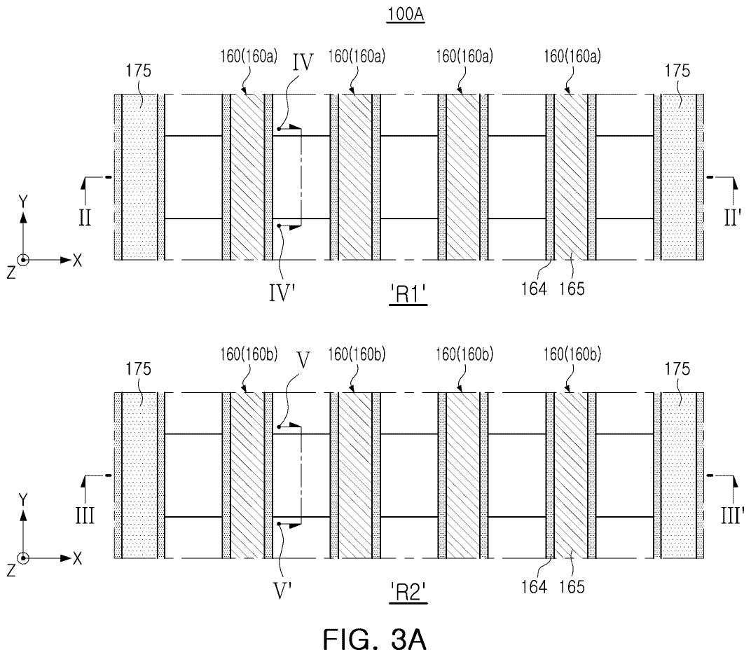

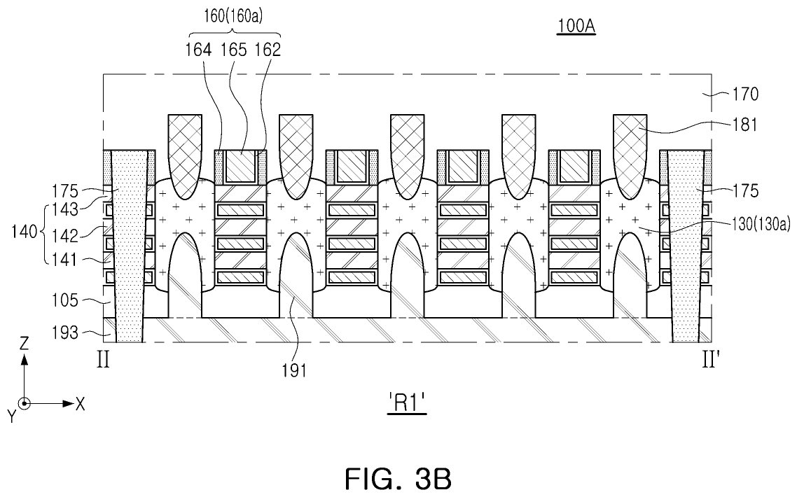

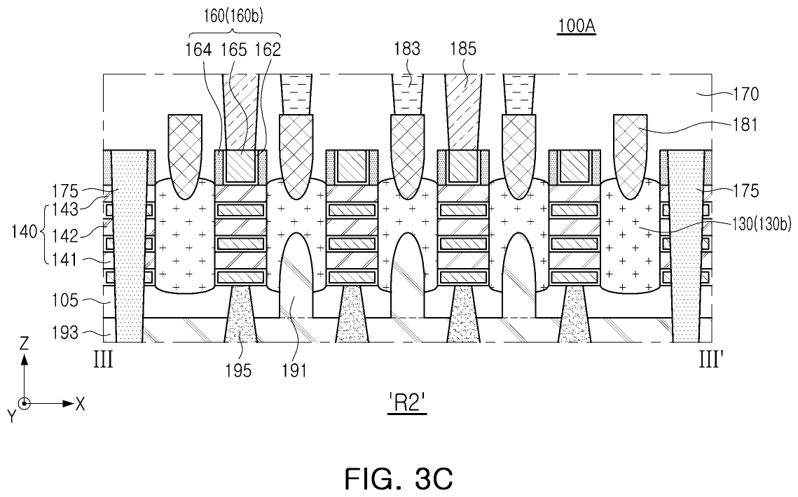

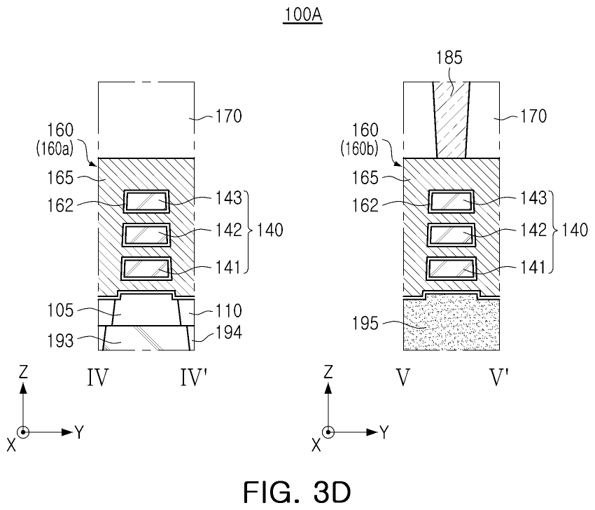

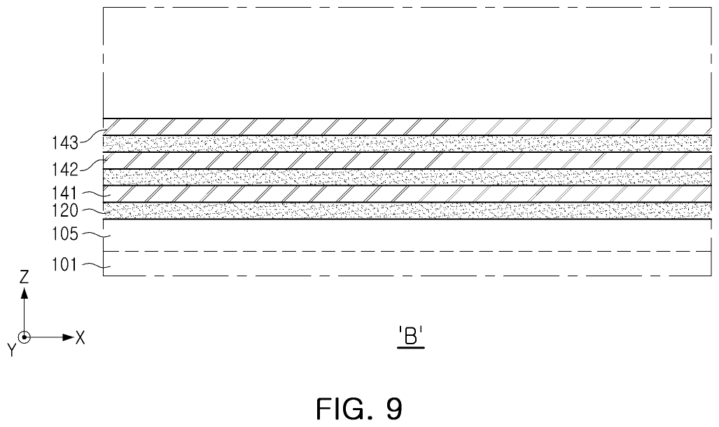

The active region 105 may have an upper surface extending in the first direction (for example, an X-direction). The active region 105 may include a semiconductor material, such as a group IV semiconductor, a group III-V compound semiconductor, or a group II-VI compound semiconductor. For example, the group IV semiconductor may include silicon, germanium, or silicon-germanium. Referring to FIG. 9 together, the active region 105 may be a component included in a substrate 101 having an upper surface extending in an X-direction and a Y-direction, and at least a portion of the substrate 101 may be removed as a manufacturing method progresses, so that the active region 105, a portion of the substrate 101, may remain in the semiconductor device 100. The substrate 101 may be provided as a bulk wafer, an epitaxial layer, a Silicon On Insulator (SOI) layer, or a Semiconductor On Insulator (SeOI) layer. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The active region 105 may be defined by a device isolation layer 110 (see FIG. 3D) formed by a shallow trench isolation (STI) process, and may be disposed to extend in one direction, for example, the X-direction. The X-direction may be defined as the first direction or the second direction. The active region 105 may partially protrude onto the device isolation layer 110 (see FIG. 3D), so that an upper surface of the active region 105 may be disposed on a higher level than an upper surface of the device isolation layer 110 (see FIG. 3D). On both sides of the gate structure 160, the active region 105 may be partially recessed to form recessed regions, and the source/drain regions 130 may be disposed in the recessed regions.

In example embodiments, the active region 105 may or may not include a well region including impurities. For example, in the case of a P-type transistor (pFET), the well region may include N-type impurities such as phosphorus (P), arsenic (As), or antimony (Sb), and in the case of an N-type transistor (nFET), the well region may include P-type impurities such as boron (B), gallium (Ga), or indium (In). The well region may be disposed, for example, at a predetermined depth from the upper surface of the active region 105.

The device isolation layer 110 (see FIG. 3D) defining the active region 105 may be formed of an insulating material, for example, an oxide, a nitride, or combinations thereof.

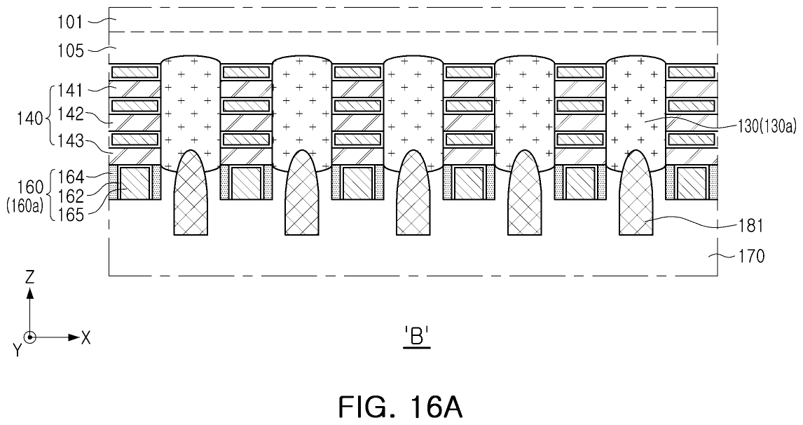

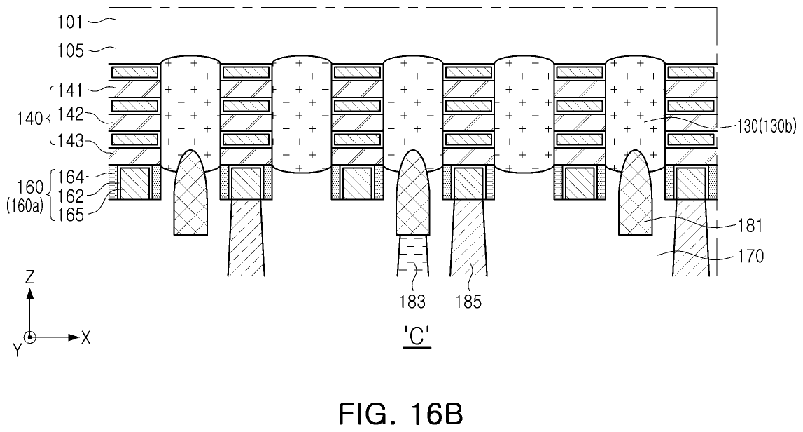

In an example embodiment, the active region 105 may be completely removed during a process and may be replaced with an insulating layer. For example, in a rear process of FIG. 16A below, not only the substrate 101 but also the active region 105 may be completely removed, and a space from which the active region 105 is removed may be filled with an insulating material and may be replace with an insulating layer.

The channel structures 140 may be disposed on the active region 105 in regions in which the active region 105 intersects the gate structures 160 or overlaps the gate structures 160 in the Z-direction. Each of the channel structures 140 may include a plurality of channel layers, first to third channel layers 141, 142 and 143, which are spaced apart from each other in a third direction (e.g., Z-direction). The first to third channel layers 141, 142 and 143 may be disposed sequentially from a lower portion. The channel structures 140 may be connected to the source/drain regions 130. The channel structures 140 may have a width identical to or similar to the gate structures 160 in the X-direction. The number and shape of the channel layers included in one channel structure 140 may vary in example embodiments. For example, one channel structure 140 may include four channel layers, and may include two channel layers or five or more channel layers.

The channel structures 140 may be formed of a semiconductor material, for example, at least one of silicon (Si), silicon germanium (SiGe), or germanium (Ge). The channel structures 140 may be formed of, for example, the same material as the active region 105. In some example embodiments, the channel structures 140 may include an impurity region disposed in a region adjacent to the source/drain regions 130.

The gate structures 160 may be disposed to extend in one direction, for example, the Y-direction, by intersecting the active region 105 and the channel structures 140 on the active region 105 and the channel structures 140. The Y-direction may be defined as the second direction or the first direction. When the active region 105 is defined as extending in the first direction, the gate structures 160 may be defined as extending in the second direction, intersecting the first direction. Conversely, the gate structures 160 may be defined as extending in the first direction, and in this case, the active region 105 may be defined as extending in the second direction, intersecting the first direction. The active region 105 and/or the channel structures 140, intersecting the gate electrodes 165 of the gate structures 160, may form a functional channel region of the transistors.

The gate structures 160 may include first gate structures 160a not electrically connected to a front interconnection structure 215 and second gate structures 160b electrically connected to the front interconnection structure 215 through gate contacts 185. The first gate structures 160a may be disposed in the dummy region DR, and may be disposed between the second gate structures 160b in the core region CR according to an example embodiment. The second gate structures 160b may be disposed in the core region CR, and may not be disposed in the dummy region DR. Since the gate contacts 185 are not disposed on the first gate structure 160a as a dummy component, an entire upper surface of each of the first gate structures 160a may be covered with the interlayer insulating layer 170. That is, the entire upper surface of each of the first gate structures 160a may be in contact with the interlayer insulating layer 170.

Each of the gate structures 160 may include a gate electrode 165, gate dielectric layers 162, and gate spacer layers 164.

The gate dielectric layers 162 may be disposed between the active region 105 and the gate electrode 165 and between the channel structure 140 and the gate electrode 165, and may be disposed to cover at least a portion of the surfaces of the gate electrode 165. For example, the gate dielectric layers 162 may be disposed to surround all surfaces excluding an uppermost surface of the gate electrode 165. The gate dielectric layers 162 may extend between the gate electrode 165 and the gate spacer layers 164, but the present disclosure is not limited thereto. The gate dielectric layers 162 may include oxides, nitrides, or a high-κ material. The high-κ material may refer to a dielectric material having a higher dielectric constant than a silicon oxide film (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and/or praseodymium oxide (Pr₂O₃). According to example embodiments, the gate dielectric layers 162 may be formed of a multilayer film.

The gate electrode 165 may be disposed to fill a gap between the first to third channel layers 141, 142 and 143 on the active region 105 and may extend onto the channel structure 140. The gate electrode 165 may be separated from the first to third channel layers 141, 142 and 143 by the gate dielectric layers 162. The gate electrode 165 may include a conductive material, and may include, for example, a metal nitride such as a titanium nitride (TiN), a tantalum nitride (TaN), or a tungsten nitride (WN), and/or a metallic material such as aluminum (Al), tungsten (W), or molybdenum (Mo), or a semiconductor material such as doped polysilicon. According to example embodiments, the gate electrode 165 may be formed of two or more multilayers.

The gate spacer layers 164 may be disposed on both or opposing side surfaces of the gate electrode 165 on the channel structure 140. The gate spacer layers 164 may insulate the source/drain regions 130 from the gate electrode 165. The gate spacer layers 164 may be formed of a multilayer structure, according to example embodiments. The gate spacer layers 164 may be formed of at least one of an oxide, a nitride or an oxynitride, and may be formed of, for example, a low-κ film.

In an example embodiment, a gate capping layer including an insulating material may be disposed on the gate structure 160. The gate capping layer may include, for example, at least one of an oxide, a nitride or an oxynitride.

The source/drain regions 130 may be disposed in recessed regions obtained by partially recessing an upper portion of the active region 105 on both sides of the gate structure 160. The recessed regions may extend along side surfaces of the channel structures 140 and side surfaces of the gate dielectric layers 162. The source/drain regions 130 may be disposed so as to cover X-directional side surfaces of each of the first to third channel layers 141, 142 and 143 of the channel structures 140. Upper surfaces of the source/drain regions 130 may be disposed on a level equal to or higher than that of lower surfaces of the gate electrodes 165 on the channel structures 140, and the level may be variously changed in example embodiments. In an example embodiment, side surfaces of the source/drain regions 130 may have a curvature according to the first to third channel layers 141, 142 and 143. In an example embodiment, internal spacers including an insulating material may be further disposed between the side surfaces of the source/drain regions 130 and the gate structures 160. A specific shape of the side surfaces of the source/drain regions 130 may be variously changed in example embodiments. The source/drain regions 130 may be epitaxially grown regions, and may include a plurality of epitaxial layers. Epitaxially grown surfaces of the source/drain regions 130 may be in contact with the channel structures 140 and the interlayer insulating layer 170. The source/drain regions 130 may include first source/drain regions 130a disposed on side surfaces of the first gate structures 160a and second source/drain regions 130b disposed on side surfaces of the second gate structures 160b. The first source/drain regions 130a disposed on side surfaces of the first gate structures 160a as a dummy component may also be a dummy component.

The source/drain regions 130 may include a semiconductor material, for example, at least one of silicon (Si) or germanium (Ge), and may further include dopants. For example, for an nFET, the dopants may be at least one of phosphorus (P), arsenic (As) or antimony (Sb). For example, for a pFET, the dopants may be at least one of boron (B), gallium (Ga) or indium (In).

The interlayer insulating layer 170 may be disposed to cover the source/drain regions 130 and the gate structures 160. In an example embodiment, the interlayer insulating layer 170 may include a plurality of insulating layers. The interlayer insulating layer 170 may include at least one of an oxide, a nitride or an oxynitride, and may include, for example, a low-κ material.

The front side contacts 181 may be connected to the source/drain regions 130 and may transmit power to the source/drain regions 130. The first source/drain regions 130a may be a dummy component, and the front side contacts 181 connected to the first source/drain regions 130a may be electrically isolated from the front interconnection structure 215. The front side contacts 181 may penetrate through the interlayer insulating layer 170 and may be disposed to recess the source/drain region 130 from an upper portion. That is, upper portions of the source/drain regions 130 may include respective recesses therein, and the front side contacts 181 may extend into the respective recesses. The front side contacts 181 may have a side surface that is inclined, toward the active region 105 due to an aspect ratio, that is, so that a width thereof decreases as a level decreases, but, the present disclosure is not limited thereto. The front side contacts 181 may extend below a lower surface of the third channel layer 143 from an upper portion of the channel structure 140 according to an example embodiment, and may extend below a lower surface of the second channel layer 142 according to an example embodiment. Although not illustrated in detail, the front side contacts 181 may include a metal-semiconductor compound layer disposed along a surface in which the source/drain regions 130 are recessed, and a conductive layer on the metal-semiconductor compound layer. The metal-semiconductor compound layer may include a metal element and a semiconductor element, and may include, for example, at least one of TiSi, CoSi, MoSi, LaSi, NiSi, TaSi or WSi. A conductive layer included in the front side contacts 181 may include, for example, a metallic material such as tungsten (W), cobalt (Co), molybdenum (Mo), copper (Cu), ruthenium (Ru), and/or aluminum (Al).

The backside contacts 191 may be connected to the source/drain regions 130 and may transmit power to the source/drain regions 130. The backside contacts 191 may be disposed to penetrate through the active region 105 and to recess the source/drain region 130 from a lower portion. The backside contacts 191 may have a side surface inclined so that a width thereof decreases as the level increases due to the aspect ratio, but the present disclosure is not limited thereto. The backside contacts 191 may extend above an upper surface of a first channel layer 141 as a first channel layer from a lower portion of the channel structure 140, as in this example embodiment, and may extend above the lower surface of the second channel layer 142 according to an example embodiment. Although not specifically illustrated, the backside contacts 191 may include a metal-semiconductor compound layer in which the source/drain regions 130 are disposed along the recessed surface, and a conductive layer below the metal-semiconductor compound layer. The metal-semiconductor compound layer may include a metal element and a semiconductor element, and may include, for example, at least one of TiSi, CoSi, MoSi, LaSi, NiSi, TaSi or WSi. The conductive layer included in the backside contacts 191 may include, for example, a metallic material such as tungsten (W), cobalt (Co), molybdenum (Mo), copper (Cu), ruthenium (Ru), and/or aluminum (Al).

Since the front side contacts 181 and the backside contacts 191 connected to the first source/drain regions 130a are dummy components, the front side contacts 181 and the backside contacts 191 may not be electrically connected to the front interconnection structure 215 and the rear interconnection structure 255. Upper vias 183 may not be disposed on the front side contacts 181 connected to the first source/drain regions 130a, and an entire upper surface of each of the front side contacts 181 connected to the first source/drain regions 130a may be covered with the interlayer insulating layer 170. That is, the entire upper surface of each of the front side contacts 181 connected to the first source/drain regions 130a may be in contact with the interlayer insulating layer 170. On the other hand, the front side contacts 181 connected to the second source/drain regions 130b may be electrically connected to the front interconnection structure 215 through the upper vias 183, and the backside contacts 191 connected to the second source/drain regions 130b may be electrically connected to the rear interconnection structure 255. In the present disclosure, the front side contacts 181 and the backside contacts 191 may be connected to the first source/drain regions 130a which is a dummy component, so that even in the dummy component, heat exchange and electrical signal transmission between an upper portion and a lower portion may be performed to provide a semiconductor device having improved reliability.

The rear power rail 193 may be electrically connected to the backside contacts 191 below the backside contacts 191. In an example embodiment, the rear power rail 193 may extend in the first direction in which the active region 105 extends below the active region 105, for example, the X-direction. In an example embodiment, the rear power rail 193 may be formed simultaneously with the backside contacts 191 so that the rear power rail 193 and the backside contacts 191 may be integrally formed (e.g., formed as a unitary element free of visible interfaces therebetween). The rear power rail 193 may form a BSPDN that applies a power or ground voltage, together with the backside contacts 191. In an example embodiment, the rear power rail 193 may include a via region and/or a line region. The rear power rail 193 may include a conductive material, and may include, for example, at least one of tungsten (W), copper (Cu), aluminum (Al), cobalt (Co), ruthenium (Ru), titanium (Ti) or molybdenum (Mo).

The rear power rail 193 disposed in the dummy region DR may be separated from a portion disposed in the core region CR by the lower blocking structure 195, and a portion disposed in the dummy region DR may not be electrically connected to the rear interconnection structure 255. In an example embodiment, the rear power rail 193 may be formed such that the portion disposed in the dummy region DR and the portion disposed in the core region CR are separated from each other.

The lower blocking structures 195 may penetrate through the active region 105 below the gate structures 160 and may separate the active region 105. The lower blocking structures 195 may block leakage current that may occur in the active region 105 below the gate structures 160. The lower blocking structures 195 may be in contact with lower surfaces of the gate structures 160. In an example embodiment, the lower blocking structures 195 may penetrate through the rear power rail 193, and may separate or divide the rear power rail 193. The lower blocking structures 195 may have a shape in which a width thereof decreases as the level increases, but the present disclosure is not limited thereto. For example, in some example embodiments, the lower blocking structures 195 may have a shape in which, as the level increases, a width thereof increases and then decreases again. In the second direction (e.g., the Y-direction), a width of each of the lower blocking structures 195 may be equal to or greater than a width of the active region 105. The lower blocking structures 195 may include an insulating material, and may include, for example, at least one of an oxide, a nitride, and an oxynitride. The lower blocking structures 195 may be disposed within the core region CR and may not be disposed within the dummy region DR. In an example embodiment, when the active region 105 is removed and replaced with an insulating layer, the lower blocking structures 195 may not be disposed.

The gate contacts 185 may be electrically connected to the second gate structures 160b on the second gate structures 160b. The gate contacts 185 may penetrate through the interlayer insulating layer 170 and may be disposed on the second gate structures 160b. The gate contacts 185 may electrically connect the front interconnection structure 215 of the front interconnection layer FML to the second gate structures 160b, and may transmit an electrical signal to the second gate structures 160b. The gate contacts 185 may be disposed on the second gate structures 160b disposed in the core region CR, and may not be disposed on the first gate structures 160a.

The upper vias 183 may be electrically connected to the front side contacts 181 on the front side contacts 181. The upper vias 183 may electrically connect the front interconnection structure 215 of the front interconnection layer FML to the front side contacts 181, and may transmit power to the source/drain regions 130. The upper vias 183 may not be disposed in the dummy region DR.

The front interconnection layer FML may include components formed by a rear End Of Line (BEOL) process, for example, the front interconnection structure 215 and a front insulating layer 225 covering the front interconnection structure 215.

The front interconnection structure 215 may be disposed in the front interconnection layer FML on the active layer ACL, and may include first front transmission lines 215a and second front transmission lines 215b sequentially stacked within the core region CR.

The first front transmission lines 215a may extend in the first direction, for example, in the X-direction, and the second front transmission lines 215b and the first front transmission lines 215a may be alternately stacked and may extend in the second direction, e.g., the Y-direction. Although not illustrated in detail, the first front transmission lines 215a and the second front transmission lines 215b disposed on different levels may be connected through front vias disposed therebetween. A line disposed on the lowest level of the front interconnection structure 215 and connected to the upper vias 183 or the gate contacts 185 in the active layer ACL may be the first front transmission line 215a extending in the first direction. Each of the first front transmission lines 215a and the second front transmission lines 215b may be a power transmission line or a signal transmission line. The power transmission line may supply different power voltages (e.g., VDD or VSS) to the semiconductor device, respectively, and may be electrically connected to the source/drain regions 130 in the active layer ACL. The signal transmission lines may supply an electrical signal to the semiconductor device, and may be electrically connected to the gate structures 160. The front interconnection structure 215 may be disposed in the core region CR, and may not be disposed in the dummy region DR. The front interconnection structure 215 may be electrically connected to the second gate structures 160b or the source/drain regions 130 disposed in the core region CR of the active layer ACL, but may not electrically connected to the first gate structures 160a or the source/drain regions 130 disposed in the dummy region DR of the active layer ACL and may be electrically isolated therefrom.

The front interconnection structure 215 may include a conductive material, and may include, for example, at least one of aluminum (Al), copper (Cu), tungsten (W) or ruthenium (Ru).

The front insulating layer 225 may cover the front interconnection structure 215 and may include a plurality of insulating layers. For example, the front insulating layer 225 may include a plurality of insulating layers disposed and stacked on the same level as each of the lines. The front insulating layer 225 may include an insulating material, and may include, for example, oxide, nitride, or oxynitride.

The rear interconnection layer BML may include a rear interconnection structure 255 for applying power to the rear power rail 193 and the backside contacts 191, and a rear insulating layer 265 covering the rear interconnection structure 255.

The rear interconnection structure 255 may include first rear transmission lines 255a extending in the first direction, for example, in the X-direction, and second rear transmission lines 255b alternately stacked with the first rear transmission lines 255a and extending in the second direction, for example, a Y-direction. Although not illustrated in detail, the first rear transmission lines 255a and the second rear transmission lines 255b disposed on different levels may be connected through rear vias disposed therebetween. The rear interconnection structure 255 may be electrically connected to the source/drain regions 130 in the active layer ACL, and may supply different power voltages (e.g., VDD or VSS) to the source/drain regions 130, respectively. The rear interconnection structure 255 may be disposed in the core region CR, and may not be disposed in the dummy region DR. The rear interconnection structure 255 may be electrically connected to the second source/drain regions 130b in the core region CR, and may not be electrically connected to the first source/drain regions 130a in the dummy region DR.

The rear insulating layer 265 may cover the rear interconnection structure 255, and may include a plurality of insulating layers. For example, the rear insulating layer 265 may include a plurality of insulating layers disposed and stacked on the same level as each of the lines. The rear insulating layer 265 may include an insulating material, and may include, for example, oxide, nitride, or oxynitride.

The semiconductor device 100 may be packaged by inverting the structure of FIG. 2B upside down so that the rear interconnection layer BML is disposed in an upper portion, but a packaging type of the semiconductor device 100 is not limited thereto.

In the description of the example embodiments below, descriptions overlapping the description described above with reference to FIGS. 1 and 2A to 2D will be omitted.

FIG. 3A is a schematic plan view illustrating a semiconductor device according to example embodiments. For convenience of description, only some components of the semiconductor device are illustrated in FIG. 3A.

FIG. 3B is a schematic cross-sectional view illustrating a semiconductor device according to example embodiments. FIG. 3B schematically illustrates a cross-section taken along cutting line II-II′ of the semiconductor device of FIG. 3A.

FIG. 3C is a schematic cross-sectional view illustrating a semiconductor device according to example embodiments. FIG. 3C schematically illustrates a cross-section taken along cutting line III-III′ of the semiconductor device of FIG. 3A.

FIG. 3D is a schematic cross-sectional view illustrating a semiconductor device according to example embodiments. FIG. 3C schematically illustrates a cross-section taken along cutting lines IV-IV′ and V-V′ of the semiconductor device of FIG. 3A.

Referring to FIG. 3A. 3B, 3C, and 3D, a semiconductor device 100A may include a first region R1 and a second region R2. The first region R1 may be an example of a non-functional region, and the second region R2 may be an example of a functional region. Referring to FIGS. 1 and 2A, 2B, 2C, and 2D together, the first region R1 may be a region included in the dummy region DR, but the present disclosure is not limited thereto. For example, the first region R1 may be a non-functional region that may be disposed within the core region CR. The components within the first region R1 may not be electrically connected to the front interconnection structure 215 and the rear interconnection structure 255 and may be electrically isolated therefrom. The second region R2 may be a region included within the core region CR, and may include components connected to the front interconnection structure 215 and the rear interconnection structure 255.

When the first region R1 is a region included in the dummy region DR, a region illustrated in FIG. 3B may be a region corresponding to FIG. 2C. A region illustrated in FIG. 3C may be a region corresponding to FIG. 2D.

When the first region R1 is a non-functional region included in the core region CR, Failure Analysis (FA) and heat exchange between an upper portion and a lower region may be performed even in the non-functional region within the core region CR, thereby providing a semiconductor device having improved reliability and heat dissipation characteristics.

Unlike the semiconductor device 100 of FIGS. 2A, 2B, 2C, and 2D, the semiconductor device 100A may further include separation structures 175 penetrating through the gate structure 160 and separating or dividing the gate structure 160. The separation structures 175 may extend in the second direction (e.g., Y-direction) and the third direction (e.g., Z-direction). The separation structure 175 disposed in the first region R1 may separate the first region R1, which is a non-functional region, from a peripheral functional region when the first region R1 is a region included in the core region CR. The separation structure 175 disposed in the second region R2 may penetrate through the second gate structure 160b and may separate or divide the transistors disposed adjacently. The separation structures 175 may extend in the third direction and may penetrate through the active region 105 and the rear power rail 193. In an example embodiment, upper surfaces of the separation structures 175 may be disposed on the same level as an upper surface of the gate electrode 165. The separation structures 175 may include an insulating material, and may include an oxide, a nitride, or an oxide.

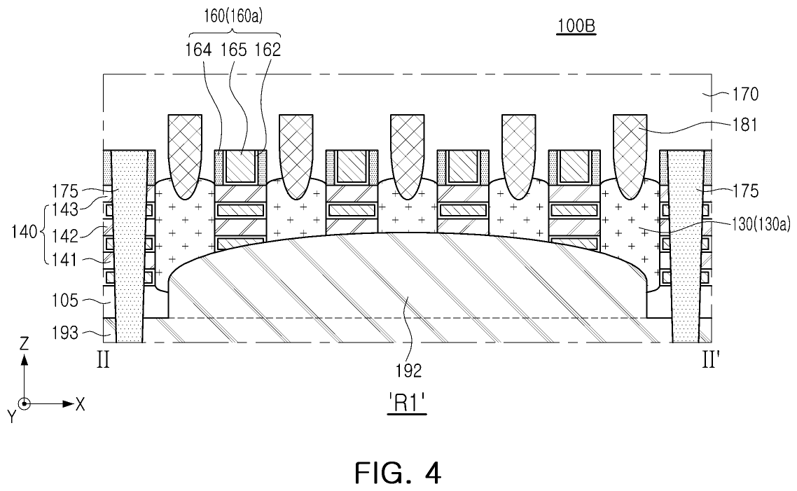

FIGS. 4, 5, 6A, and 6B are schematic cross-sectional views illustrating semiconductor devices according to example embodiments. FIGS. 4, 5, 6A, and 6B illustrate regions corresponding to FIG. 3B.

Referring to FIG. 4, a semiconductor device 100B may include a lower conductive structure 192 disposed so that a plurality of first gate structures 160a and first source/drain regions 130a disposed on both sides thereof are partially recessed from a lower surface. Since the plurality of first gate structures 160a and the first source/drain regions 130a are dummy components, the lower conductive structure 192 may be formed with a large width so as to be in contact with all of these components and may further improve the heat exchange capability between an upper portion and a lower portion.

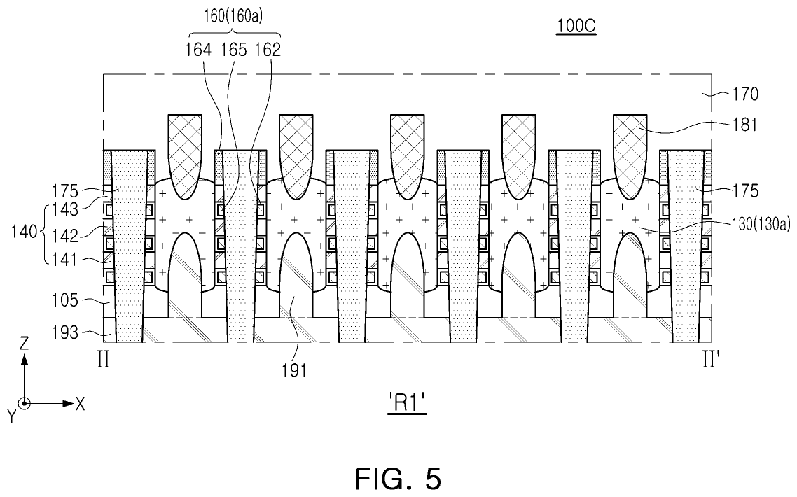

Referring to FIG. 5, a semiconductor device 100C may have separation structures 175 formed to penetrate through all of the plurality of first gate structures 160a included in the first region R1, unlike the semiconductor device 100 of FIGS. 2A, 2B, 2C, and 2D. Since the first region R1 corresponds to the dummy region DR of FIG. 2 or illustrates a non-functional region within the core region CR, all of the included first gate structures 160a may be separated.

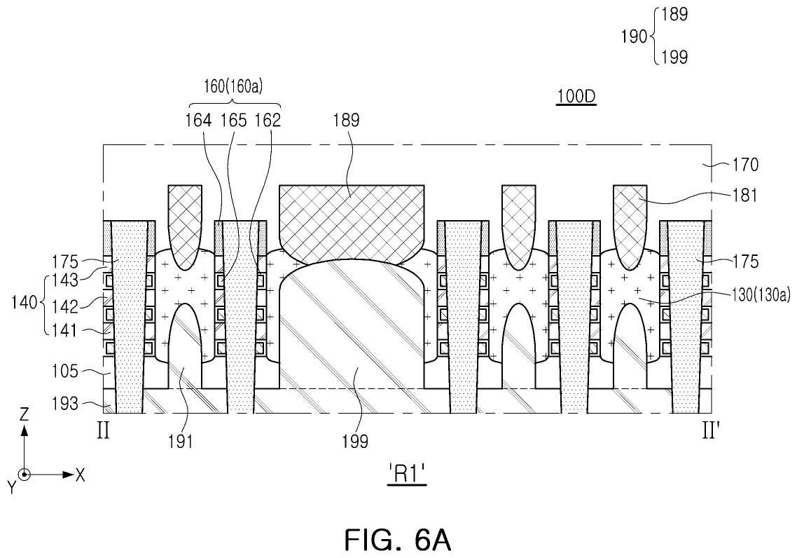

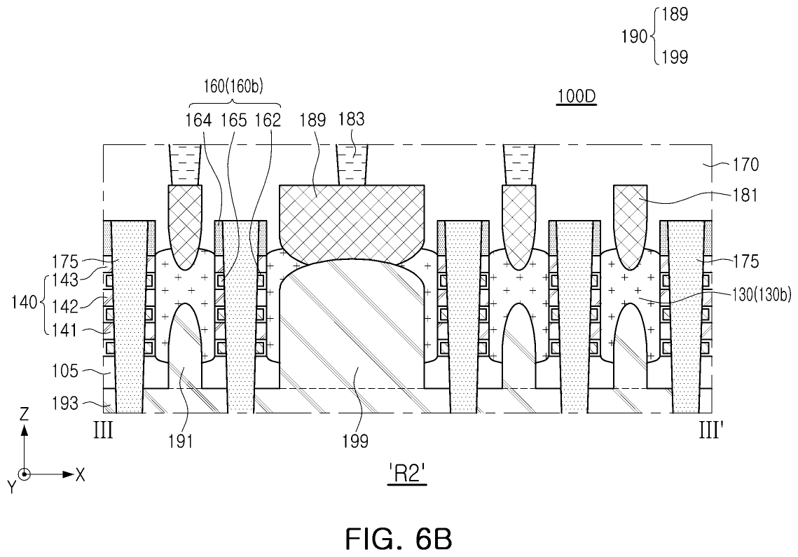

Referring to FIGS. 6A and 6B, a semiconductor device 100D may further include a conductive connection structure 190, unlike the semiconductor device 100 of FIGS. 2A to 2D. The conductive connection structure 190 may include a first portion 189 and a second portion 199. The first portion 189 may be formed by the same process as the front side contacts 181, and may be formed with a larger width and a larger height than the front side contacts 181. However, unlike the front side contacts 181 being formed by partially recessing upper surfaces of the source/drain regions 130, the first portion 189 may be disposed by recessing the gate structure 160 and the source/drain regions 130 on both sides thereof from an upper surface thereof. The second portion 199 may be formed by the same process as the backside contacts 191, and may be formed with a larger width and a larger height than the backside contacts 191. However, unlike the backside contacts 191 being formed by partially recessing lower surfaces of the source/drain regions 130, the second portion 199 may be disposed by recessing lower surfaces of the gate structure 160 and the source/drain regions 130 on both sides thereof. The first portion 189 and the second portion 199 may be merged with each other to form a single conductive connection structure 190. The conductive connection structure 190 disposed in the second region R2 may be connected to the front interconnection structure 215 of FIG. 2 through the upper via 183, may be connected to the rear interconnection structure 255, and may transmit an electrical signal or power between an upper portion and a lower portion. The conductive connection structure 190 disposed in the first region R1 may not be electrically connected to the front interconnection structure 215 and the rear interconnection structure 255, and may not have an upper via 183 disposed on an upper surface thereof. The conductive connection structure 190 disposed in the first region R1 may transmit heat between the upper portion and the lower portion, or may transmit an electrical signal for FA when necessary.

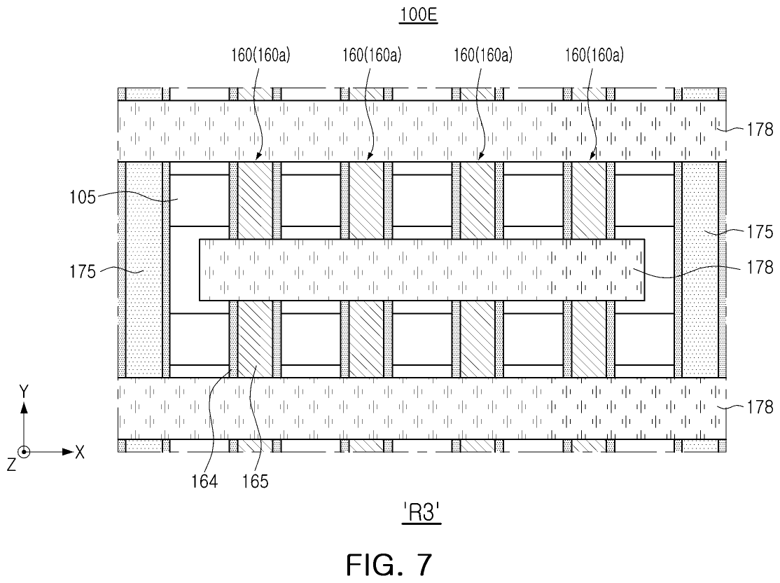

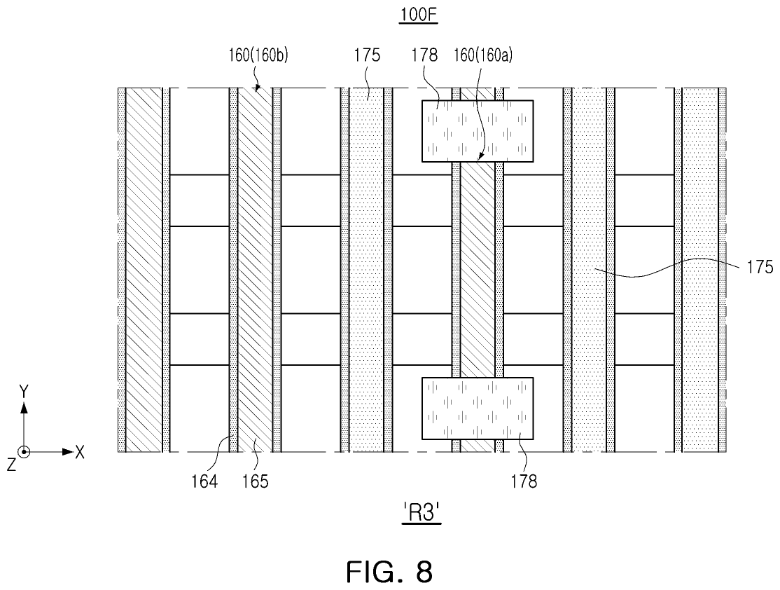

FIGS. 7 and 8 are plan views illustrating semiconductor devices according to example embodiments. FIGS. 7 and 8 illustrate a third region R3, different from the first region R1 and the second region R2 of FIGS. 3A, 3B, 3C, and 3D. The third region R3 may be a region included in the core region CR of FIGS. 2A, 2B, 2C, and 2D.

Referring to FIG. 7, a semiconductor device 100E may include a third region R3, and may include a separation structure 175 extending in the second direction within the third region R3 to separate the gate structure 160, and a separation pattern 178 extending in the first direction to separate the gate structures 160 and the separation structure 175. The third region R3 may be a non-functional region arranged within the core region CR of FIGS. 2A, 2B, 2C, and 2D, and the separation structure 175 and the separation pattern 178 may electrically isolate the peripheral functional region from the third region R3 as a non-functional region. The separation pattern 178 may include an insulating material, and may include, for example, an oxide, a nitride, or an oxynitride. The features of the dummy region DR or the first region R1 of the semiconductor devices 100, 100A, 100B, 100C and 100D described above may be applied in the third region R3 of the semiconductor device 100E of FIG. 7

Referring to FIG. 8, a semiconductor device 100F may be configured so that a third region R3 may include a functional region and a non-functional region, unlike the semiconductor device 100E of FIG. 7. The functional region and the non-functional region may be electrically isolated by the separation structure 175 and the separation pattern 178. The first gate structure 160a, which is a dummy component, may be surrounded by the separation structure 175 and the separation pattern 178, and a region in which the first gate structure 160a is disposed is a non-functional region, to which the features of the dummy region DR or the first region R1 of the semiconductor devices 100, 100A, 100B, 100C and 100D described above may be applied. A region in which the second gate structures 160b are disposed is a functional region, to which the features of the core region CR or the second region R2 of the semiconductor devices 100, 100A, 100B, 100C and 100D described above may be applied.

FIGS. 9 to 14, FIGS. 15A, 16A and 17A are cross-sectional views illustrating a method of manufacturing a semiconductor device according to example embodiments in accordance with the process sequence. FIGS. 9 to 14, FIGS. 15A, 16A and 17A illustrate region ‘B’ corresponding to FIG. 2C.

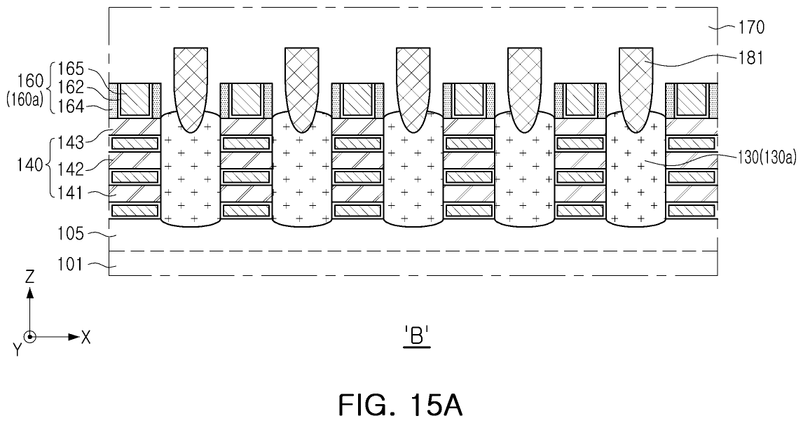

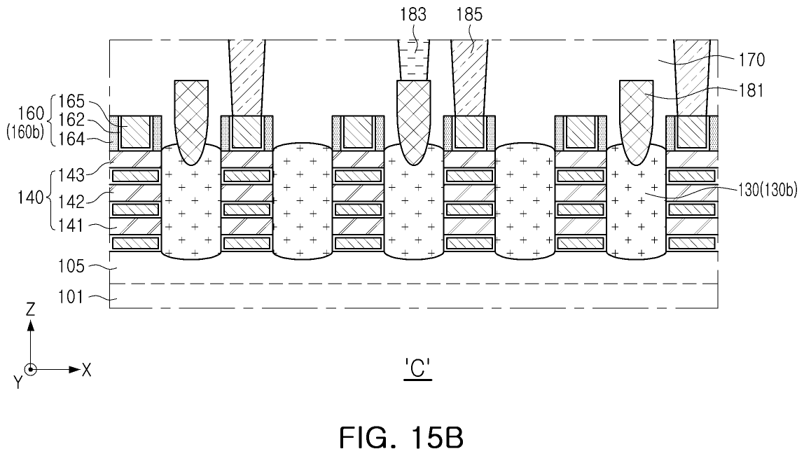

FIGS. 15B, 16B and 17B are cross-sectional views illustrating a method of manufacturing a semiconductor device according to example embodiments in accordance with the process sequence. FIGS. 15B, 16B and 17B illustrate region ‘C’ corresponding to FIG. 2D. The manufacturing method performed prior to FIG. 15B may be the same as the manufacturing method of region ‘B’ of FIGS. 9 to 14, FIGS. 15A, 16A and 17A.

Referring to FIG. 9, a plurality of sacrificial layers 120 and a plurality of channel layers 141, 142 and 143 may be alternately stacked on a substrate 101, and the plurality of channel layers 141, 142 and 143 and the substrate 101 may be partially removed to form an active structure including an active region 105.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The plurality of channel layers 141, 142 and 143 may include the first to third channel layers 141, 142 and 143, and the sacrificial layers 120 may be alternately stacked with the plurality of channel layers 141, 142 and 143. The plurality of sacrificial layers 120 may be layers replaced with the gate dielectric layers 162 and gate electrodes 165 below the first to third channel layers 141, 142 and 143 through a subsequent process, as illustrated in FIGS. 2B and 2C. The sacrificial layers 120 may be formed of a material having etch selectivity with respect to the first to third channel layers 141, 142 and 143, respectively. The first to third channel layers 141, 142 and 143 may include a different material from the sacrificial layers 120. The sacrificial layers 120 and the first to third channel layers 141, 142 and 143 may include a semiconductor material, for example, including at least one of silicon (Si), silicon germanium (SiGe) or germanium (Ge), but may include different materials and may or may not include impurities. For example, the sacrificial layers 120 may include silicon germanium (SiGe), and the first to third channel layers 141, 142 and 143 may include silicon (Si).

The sacrificial layers 120 and the first to third channel layers 141, 142 and 143 may be formed by performing an epitaxial growth process from the stack structure. The number of layers of the channel layers alternately stacked with the sacrificial layers 120 may be variously changed in example embodiments.

The active structure may include an active region 105, a plurality of sacrificial layers 120, and first to third channel layers 141, 142 and 143. The active structure may be formed in a line shape extending in one direction, for example, in the X-direction, and may be formed spaced apart from the adjacent active structure in the Y-direction. The side surfaces of the active structure in the Y-direction may be coplanar with each other, and may be disposed on a straight line.

In a region from which portions of the active region 105, the plurality of sacrificial layers 120 and the first to third channel layers 141, 142 and 143 are removed, the device isolation layer 110 (see FIG. 3d) may be formed by filling the insulating material and then partially removing the insulating material so that the active region 105 protrudes. The active region 105 may be formed as a portion of the substrate 101 or may include an epitaxial layer grown from the substrate 101.

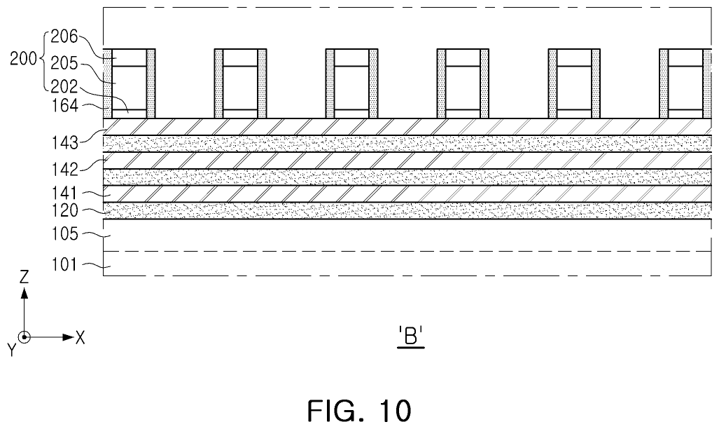

Referring to FIG. 10, sacrificial gate structures 200 and gate spacer layers 164 may be formed on the active structure.

Each of the sacrificial gate structures 200 may be a sacrificial structure formed in a region in which the gate dielectric layers 162 and the gate electrode 165 are disposed on the channel structure 140, as illustrated in FIGS. 2B and 2C, through a subsequent process. The sacrificial gate structures 200 may have a line shape extending in one direction, intersecting the active structure. The sacrificial gate structures 200 may extend, for example, in the Y-direction. Each of the sacrificial gate structures 200 may include first and second sacrificial gate layers 202 and 205 and a mask pattern layer 206, which are sequentially stacked. The first and second sacrificial gate layers 202 and 205 may be patterned using the mask pattern layer 206.

The first and second sacrificial gate layers 202 and 205 may be an insulating layer and a conductive layer, respectively, but the present disclosure is not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

The gate spacer layers 164 may be formed on both sidewalls of the sacrificial gate structures 200. The first sacrificial gate layer 202 may be formed with a smaller width than the second sacrificial gate layer 205, and the gate spacer layers 164 may be formed along a side surface of the first sacrificial gate layer 202 and a side surface of the second sacrificial gate layer 205. The gate spacer layers 164 may be formed of a low-κ material, and may include, for example, at least one of SiO, SiN, SiCN, SiOC, SiON or SiOCN.

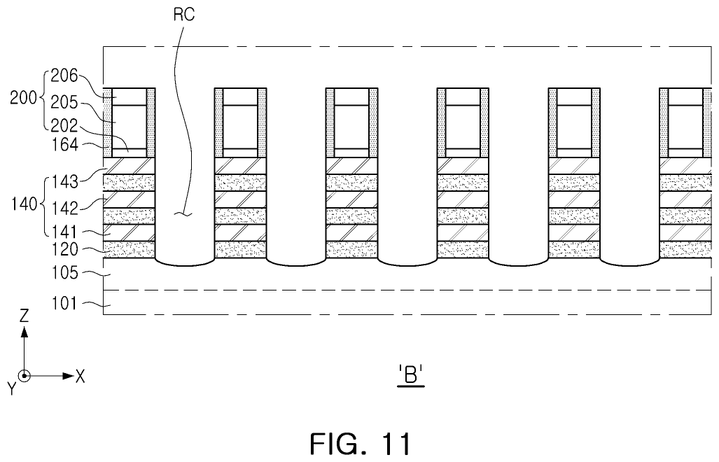

Referring to FIG. 11, an etching process using the sacrificial gate structures 200 as an etching mask may be performed, thus forming recessed regions RC penetrating the active structure and exposing the active region 105.

The sacrificial layers 120 and the first to third channel layers 141, 142 and 143 exposed from the sacrificial gate structures 200 may be partially removed to form recessed regions, and the plurality of sacrificial layers 120 may be partially removed. Accordingly, the first to third channel layers 141, 142 and 143 may form channel structures 140 having a limited length in the X-direction.

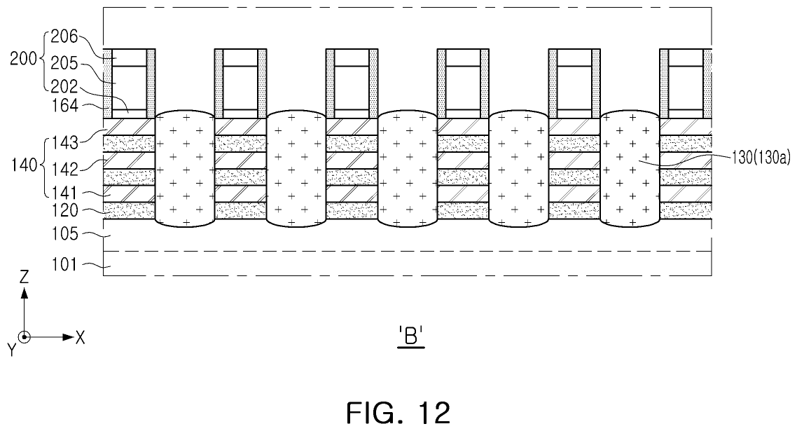

Referring to FIG. 12, a plurality of source/drain regions 130 may be formed in the recessed regions RC.

The source/drain regions 130 may be formed within the recess regions RC, and may be formed by growing from side surfaces of the active regions 105 and the channel structures 140, for example, in a selective epitaxial process.

The source/drain regions 130 may include a plurality of epitaxial layers, which may have different non-silicon concentrations. The source/drain regions 130 may include impurities by in-situ doping, and may include a plurality of layers having different doping elements and/or doping concentrations. In some example embodiments, the source/drain regions 130 may have an N-type conductivity and may be formed to include at least one dopant of boron (B), gallium (Ga), or indium (In). In some example embodiments, the source/drain region 130 may have a P-type conductivity and may be formed to include at least one dopant of phosphorus (P), arsenic (As), or antimony (Sb).

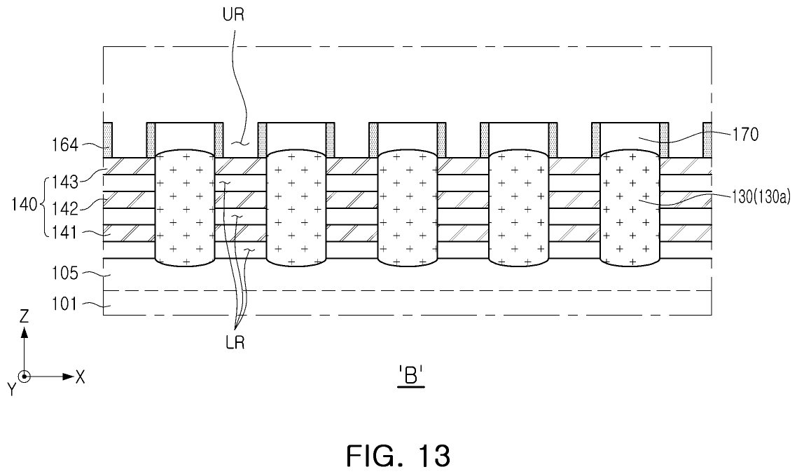

Referring to FIG. 13, an interlayer insulating layer 170 may be partially formed, and the sacrificial gate structures 200 and the plurality of sacrificial layers 120 may be removed.

The interlayer insulating layer 170 may be formed by forming an insulating film covering the sacrificial gate structures 200 and the source/drain regions 130 and performing a planarization process.

The sacrificial gate structures 200 and the plurality of sacrificial layers 120 may be selectively removed with respect to the gate spacer layers 164 and the channel structures 140. First, the sacrificial gate structures 200 may be removed to form upper gap regions UR, and then the sacrificial layers 120 exposed through the upper gap regions UR may be removed, thus forming lower gap regions LR. For example, when the plurality of sacrificial layers 120 include silicon germanium (SiGe) and the channel structures 140 include silicon (Si), the plurality of sacrificial layers 120 may be selectively removed with respect to the channel structures 140 by performing a wet etching process.

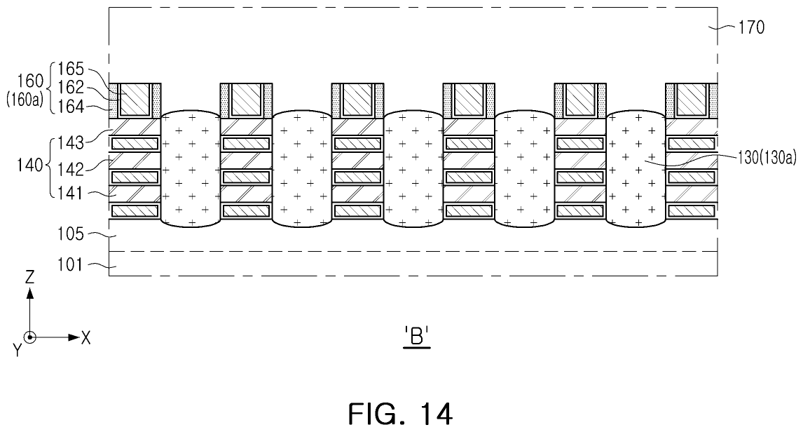

Referring to FIG. 14, gate dielectric layers 162 and gate electrodes 165 may be formed to form gate structures 160.

The gate structures 160 may be formed to fill the upper gap regions UR and the lower gap regions LR. The gate dielectric layers 162 may be formed to conformally cover internal surfaces of the upper gap regions UR and the lower gap regions LR. The gate electrode 165 may be formed to completely fill the upper gap regions UR and the lower gap regions LR and may then be removed by a predetermined depth from an upper portion in the upper gap regions UR together with the gate dielectric layers 162 and the gate spacer layers 164. Accordingly, the gate structures 160 including the gate dielectric layers 162 and the gate electrode 165 may be formed.

Referring to FIGS. 15A and 15B, front side contacts 181, upper vias 183 and gate contacts 185 may be formed.

The front side contacts 181 may be formed by forming a contact hole extending into the source/drain regions 130 by penetrating through the interlayer insulating layer 170, and then forming a metal-semiconductor compound layer and a conductive layer.

The gate contacts 185 may be formed on the gate structures 160 by penetrating the interlayer insulating layer 170. The gate contacts 185 may be electrically connected to the gate electrodes 165 of the gate structures 160.

The upper vias 183 may be formed on the front side contacts 181 by penetrating through the interlayer insulating layer 170 and may be electrically connected to the front side contacts 181.

The front side contacts 181 may be formed in both region ‘B’ and region ‘C’, but the gate contacts 185 and the upper vias 183 may not be formed in the region ‘B’ as a non-functional region.

Hereafter, referring to FIG. 2B together, a front interconnection structure 215 and a front insulation layer 225 may be formed on the interlayer insulating layer 170, the upper vias 183 and the gate contacts 185. First front transmission lines 215a and second front transmission lines 215b may be formed sequentially from a lower portion, and may be formed in the core region CR and may be electrically connected to the upper vias 183 or the gate contacts 185. The front insulation layer 225 may be sequentially stacked on the same level as the first front transmission lines 215a and the second front transmission lines 215b and may be formed of a plurality of layers.

Referring to FIGS. 16A and 16B, at least a portion of the substrate 101 may be removed.

In order to perform the process from the bottom surface of the substrate 101 of FIGS. 15A and 15B, a separate carrier substrate may be formed on the front side interconnection layer FML and an entire structure may be turned over to perform the following processes. The substrate 101 may be thinned by removing a portion thereof, for example, by a lapping, grinding, and/or polishing process. In some example embodiments, the active region 105 and the device isolation layer 110 (see FIG. 3D) may be partially removed. In some example embodiments, the substrate 101 and the active region 105 may be completely removed.

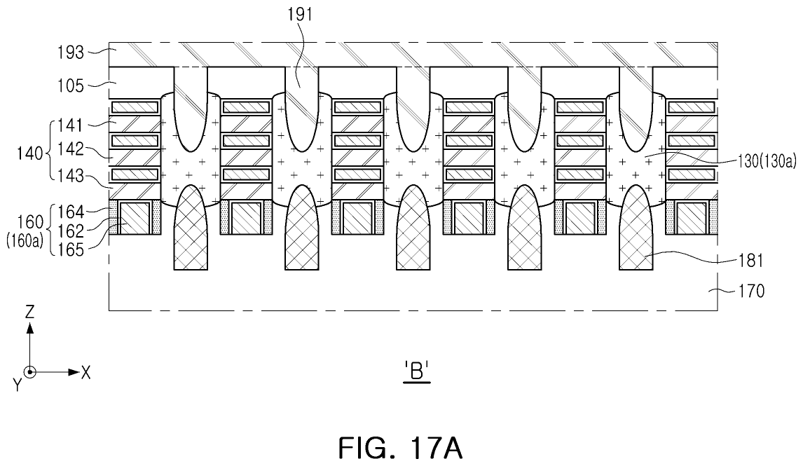

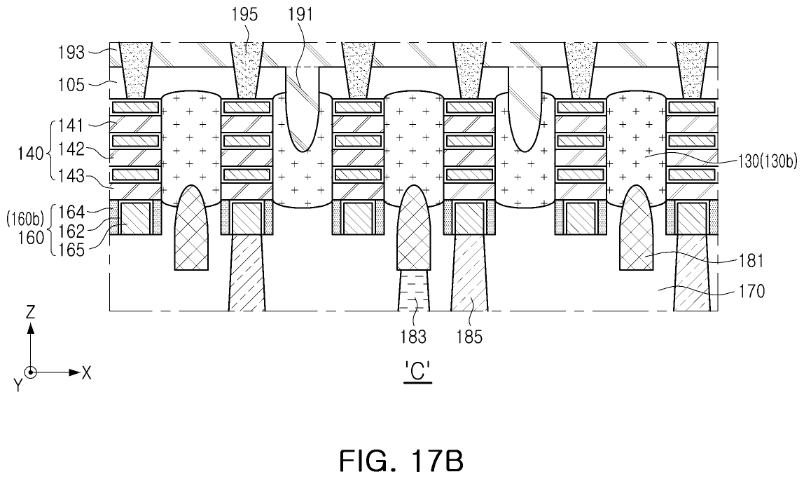

Referring to FIGS. 17A and 17B, backside contacts 191, rear power rail 193, and a lower blocking structure 195 may be formed to form components included in the active layer ACL.

The lower blocking structure 195 penetrating through the active region 105 may be formed, and the backside contacts 191 and the rear power rail 193 may be formed. The lower blocking structure 195 may be formed by forming a hole penetrating through the active region 105 and exposing the gate structures 160, and then depositing an insulating material in the hole. The backside contacts 191 may be formed by forming a hole penetrating through the active region 105 to partially recess the source/drain regions 130, and then filling the hole with a conductive material. The backside contacts 191 may be formed in a process identical to or similar to that of the front side contacts 181. The rear power rail 193 may be formed together with the backside contacts 191, and may be formed in a method such as depositing a conductive material covering an upper surface of the active region 105 based on FIGS. 17A and 17B. Based on FIGS. 17A and 17B, an upper surface of the lower blocking structure 195 and an upper surface of the rear power rail 193 may be formed to form a coplanar surface by an etching process such as CMP.

Referring to FIGS. 17A and 17B together with FIG. 2B, a rear interconnection structure 255 and a rear insulation layer 265 may be formed on the rear power rail 193, thus forming components included in the rear interconnection layer BML.

The rear interconnection structure 255 and the rear insulation layer 265 may be formed in a process identical to or similar to that of the front interconnection structure 215 and the front insulation layer 225.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
an active region extending in a first direction;
a gate structure on the active region and extending in a second direction intersecting the first direction;
source/drain regions on side surfaces of the gate structure and on the active region;
front side contacts on a first side of the source/drain regions;
backside contacts at least partially penetrating the active region and on a second side of the source/drain regions opposite the first side; and
an interlayer insulating layer on the gate structure, on the source/drain regions, and on the front side contacts,
wherein an entire upper surface of the gate structure that is opposite the active region in a third direction perpendicular to the first and second directions is in contact with the interlayer insulating layer.

2. The semiconductor device of claim 1,
wherein entire upper surfaces of the front side contacts opposite the first side of the source/drain regions in the third direction are in contact with the interlayer insulating layer.

3. The semiconductor device of claim 1, further comprising:
a front interconnection structure on the interlayer insulating layer,
wherein the front interconnection structure is electrically isolated from the gate structure.

4. The semiconductor device of claim 1, further comprising:
a rear power rail extending in the first direction, and contacting the active region and the backside contacts such that the active region and the backside contacts are between the rear power rail and the interlayer insulating layer.

5. The semiconductor device of claim 4, further comprising:
a rear interconnection structure, wherein the rear power rail is between the rear interconnection structure and the active region, and
wherein the rear interconnection structure is electrically isolated from the backside contacts.

6. The semiconductor device of claim 1, further comprising:
a separation structure extending in the third direction and at least partially penetrating the gate structure.

7. The semiconductor device of claim 6, further comprising:
a rear power rail extending in the first direction and contacting the active region and the backside contacts such that the active region and the backside contacts are between the rear power rail and the interlayer insulating layer,
wherein the separation structure at least partially penetrates the active region and the rear power rail.

8. The semiconductor device of claim 7,
wherein an upper surface of the separation structure is coplanar with an upper surface of the gate structure, and
a lower surface of the separation structure is coplanar with a lower surface of the rear power rail.

9. The semiconductor device of claim 6, further comprising:
a separation pattern extending in the first direction on one side of the active region, at least partially penetrating the gate structure, and separating the gate structure.

10. The semiconductor device of claim 9,
wherein the separation pattern at least partially penetrates the separation structure.

11. A semiconductor device, comprising:
an active layer comprising a core region, and a dummy region adjacent the core region, the core region comprising a plurality of gate structures spaced apart from each other in a first direction and extending in a second direction intersecting the first direction, and a plurality of source/drain regions on side surfaces of the plurality of gate structures;
a front interconnection layer on a first side of the active layer and comprising a front interconnection structure and a front insulating layer on the front interconnection structure; and
a rear interconnection layer on a second side of the active layer opposite the first side, and comprising a rear interconnection structure and a rear insulating layer on the rear interconnection structure,
wherein the plurality of gate structures comprise first gate structures in the dummy region and second gate structures in the core region,
wherein the plurality of source/drain regions comprise first source/drain regions on side surfaces of the first gate structures, and second source/drain regions on side surfaces of the second gate structures,
wherein the active layer further comprises first front side contacts extending into upper surfaces of the first source/drain regions and first backside contacts extending into lower surfaces of the first source/drain regions opposite the upper surfaces,
wherein the front interconnection structure overlaps the second gate structures in a third direction perpendicular to the first direction and the second direction and is electrically connected to the second gate structures,
wherein the rear interconnection structure overlaps the second source/drain regions in the third direction and is electrically connected to the second source/drain regions, and
wherein the first gate structures do not overlap the front interconnection structure and the rear interconnection structure in the third direction.

12. The semiconductor device of claim 11,
wherein the first source/drain regions do not overlap the front interconnection structure or the rear interconnection structure in the third direction.

13. The semiconductor device of claim 11,
wherein the active layer further comprises:
second front side contacts extending into upper surfaces of the second source/drain regions; and
second backside contacts extending into lower surfaces of the second source/drain regions opposite the upper surfaces thereof,
wherein the rear interconnection structure is electrically connected to the second source/drain regions through the second backside contacts.

14. The semiconductor device of claim 11,
wherein the active layer further comprises a conductive connection structure in the dummy region, extending in the third direction, and at least partially penetrating one of the first source/drain regions.

15. The semiconductor device of claim 14,
wherein the conductive connection structure comprises a first portion having a width that decreases toward the rear interconnection layer, and a second portion that is between the first portion and the rear interconnection layer and having a width that increases toward the rear interconnection layer.

16. The semiconductor device of claim 15,
wherein the first portion of the conductive connection structure comprises a same material as the first front side contacts, and
the second portion of the conductive connection structure comprises a same material as the first backside contacts.

17. A semiconductor device, comprising:
an active layer comprising a first region and a second region;
a first active region extending in the first region in a first direction;
a second active region extending in the second region in the first direction;
a first gate structure extending in a second direction intersecting the first direction and on the first active region of the first region;
a second gate structure extending on the second active region of the second region and in the second direction;
first source/drain regions on side surfaces of the first gate structure and on the first active region, the first source/drain regions respectively comprising a first side and a second side opposite the first side;
second source/drain regions on side surfaces of the second gate structure and on the second active region, the second source/drain regions respectively comprising a first side and a second side opposite the first side;
first front side contacts on the first side of the first source/drain regions;
a second front side contact on the first side of at least one of the second source/drain regions;
first backside contacts on the second side of the first source/drain regions opposite the first side thereof;
a second backside contact on the second side of at least one of the second source/drain regions opposite the first side thereof;
a lower blocking structure at least partially penetrating the second active region, on the second gate structure and separating the second active region;
an upper via on the second front side contact;
a gate contact on the second gate structure opposite the lower blocking structure; and
a front interconnection structure on the active layer, the front interconnection structure comprising a first front transmission line extending in the first direction and a second front transmission line extending in the second direction,
wherein the front interconnection structure is electrically connected to the second gate structure through the gate contact, and
the first gate structure is electrically isolated from the front interconnection structure.

18. The semiconductor device of claim 17,
wherein the lower blocking structure is in contact with a lower surface of the second gate structure.

19. The semiconductor device of claim 17, further comprising:
a rear interconnection structure on the active layer opposite the front interconnection structure, the rear interconnection structure comprising a first rear transmission line extending in the first direction and a second rear transmission line extending in the second direction,
wherein the rear interconnection structure is electrically connected to the second backside contact and is not electrically connected to the first backside contacts.

20. The semiconductor device of claim 17, further comprising:
a separation pattern extending in the first direction and at least partially penetrating and separating the first gate structure on sides of the first active region.
